(19) United States
(12) Patent Application Publication
(10) Pub. No.: US 2007/0152252 A1
(43) Pub. Date: Jul. 5, 2007

(54) Reducing aluminum dissolution in high pH solutions

(76) Inventors: Mark F. Buehler, Portland, OR (US); Anne E. Miller, Portland, OR (US); Tatyana N. Andryushchenko, Portland, OR (US)

Correspondence Address: INTEL CORPORATION;c/o INTELLEVATE, LLC, P.O. BOX 52050, MINNEAPOLIS, MN, 55402, US

(21) Appl. No.: 11/322,885

(22) Filed: Dec. 30, 2005

(51) Int. Cl. H01L 21/8242; H01L 21/461

(52) U.S. Cl. 257/295; 438/585; 438/633; 438/692; 438/240; 438/591; 438/785; 257/382

(57) ABSTRACT

A method for reducing the dissolution of aluminum gate electrodes in a high pH clean chemistry comprises modifying the high pH clean chemistry to include a silanol-based chemical. The silanol-based chemical causes a protective layer to form on a top surface of the aluminum gate electrode. The protective layer substantially reduces or prevents corrosion that occurs due to the high pH level of the clean chemistry. The protective layer is formed by the silanol-based chemical bonding to the aluminum gate electrode through a hydrolysis reaction, thereby forming a silanol-based protective layer.

### BACKGROUND

In the manufacture of integrated circuits, there has been a trend towards replacing conventional transistor gate stacks formed using silicon dioxide and polysilicon with gate stacks that utilize a high-k dielectric gate oxide and a metal gate electrode. In one process for forming the high-k/metal transistor gate stack, the high-k dielectric material is first deposited with a polysilicon cap and annealed. The annealing process improves the slightly imperfect molecular structure of the high-k material. A replacement metal gate process is then used to remove the polysilicon cap and deposit metal to form the metal gate electrode.

The deposited metal is planarized with a chemical mechanical polishing (CMP) process to complete the metal gate electrode. CMP is well known in the art and generally involves the use of a rotating polishing pad and an abrasive, corrosive slurry on a semiconductor wafer. After the metal is deposited, the polishing pad and the slurry physically and chemically grind flat the microscopic topographic features until the metal is planarized, thereby allowing subsequent processes to begin on a flat surface. The CMP process is generally followed by a post-CMP clean chemistry that removes residual particles and cleans the surface of the planarized metal. The post-CMP clean chemistry is most effective at a high pH level.

Certain replacement metal gate processes use aluminum metal to form the gate electrode. Unfortunately, aluminum metal is susceptible to significant corrosion when exposed to a high pH clean chemistry. The problem of aluminum corrosion has been addressed in other industries by doping the aluminum with metals such as chromium and magnesium that tend to improve the chemical resistance of the aluminum. For semiconductor processes, however, the use of dopants in the aluminum increases the electrical resistance of the metal gate electrode, thereby increasing power consumption and heat generation by the transistor and impacting work function performance. As such, alternate methods to reduce corrosion are needed.

### BRIEF DESCRIPTION OF THE DRAWINGS

FIG. 1A is an SEM image of pure aluminum metal that has been deposited but not cleaned.

FIG. 1B is an SEM image of pure aluminum metal that has been deposited and cleaned using a conventional clean chemistry.

FIG. 2 is process of forming a metal gate transistor with a protective layer in accordance with an implementation of the invention.

FIGS. 3A to 3I illustrate structures that are formed when carrying out the process of FIG. 2.

FIGS. 4A to 4C illustrate chemical reactions that may occur during the formation of a protective layer in accordance with an implementation of the invention.

FIGS. 5A to 5C illustrate chemical reactions that may occur during the formation of a protective layer in accordance with another implementation of the invention.

FIG. 6 is an SEM image of pure aluminum metal that has been deposited and cleaned using a silanol-modified clean chemistry in accordance with an implementation of the invention.

### DETAILED DESCRIPTION

Described herein are systems and methods for reducing the corrosion of metals used as gate electrodes for metal-oxide semiconductor (MOS) transistors. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

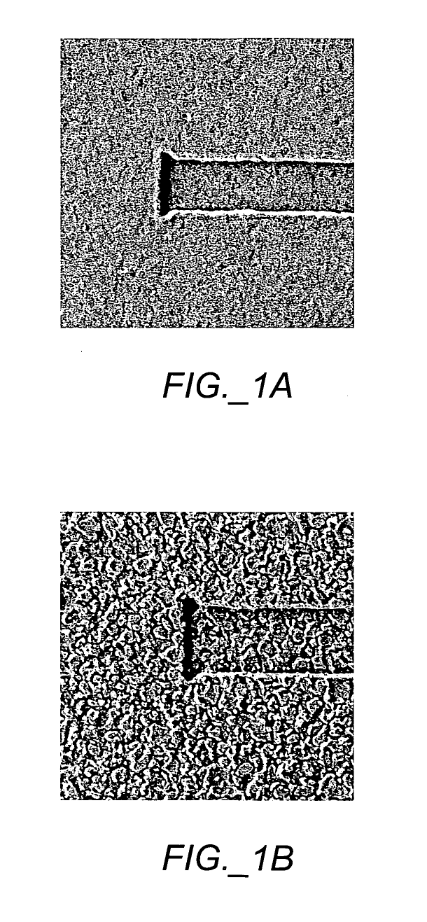

FIG. 1A is a scanning electron microscope (SEM) image of pure aluminum metal that has been deposited but not cleaned. As shown, the surface of the aluminum metal is generally smooth and substantially free of defects. FIG. 1B is an SEM image of the aluminum metal after it has been subjected to a conventional, high pH clean chemistry. As shown, the surface of the cleaned aluminum metal is now substantially pitted and corroded. This gross corrosion tends to be caused by the high pH level of the clean chemistry (e.g., a pH level of between pH 8 and pH 12, often around pH 10.5), which creates an environment in which the aluminum metal dissolves into the cleaning solution. The high pH level is necessary, however, to provide adequate particle undercut to sufficiently clean the metal surface.

Implementations of the invention provide methods to inhibit surface oxidation and dissolution of metals, for example, aluminum metal used to form a metal gate in a MOS transistor. In some implementations of the invention, a silanol-based protective layer may be formed on the metal surface to suppress surface oxidation and metal dissolution. Unlike known protective layers, silanol-based protective layers formed in accordance with the invention are relatively thin, for instance, each protective layer may be only a few monolayers thick. Furthermore, unlike conventional protective layers, the silanol-based protective layer of the invention is bonded to the metal substrate using covalent bonds. Such a protective layer may substantially prevent the metal substrate from being corroded or damaged by high pH clean chemistries.

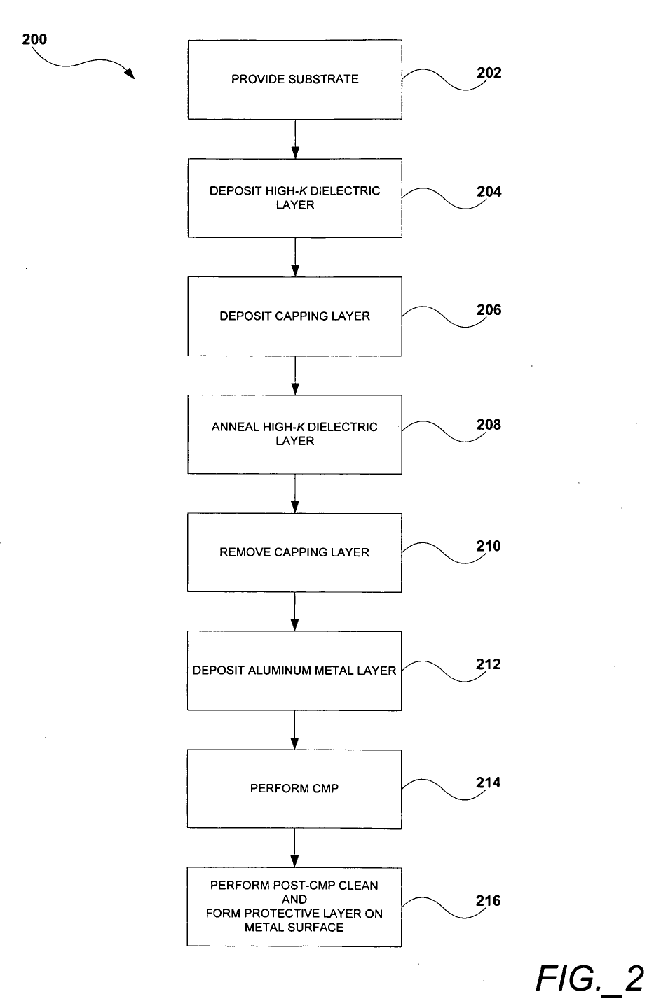

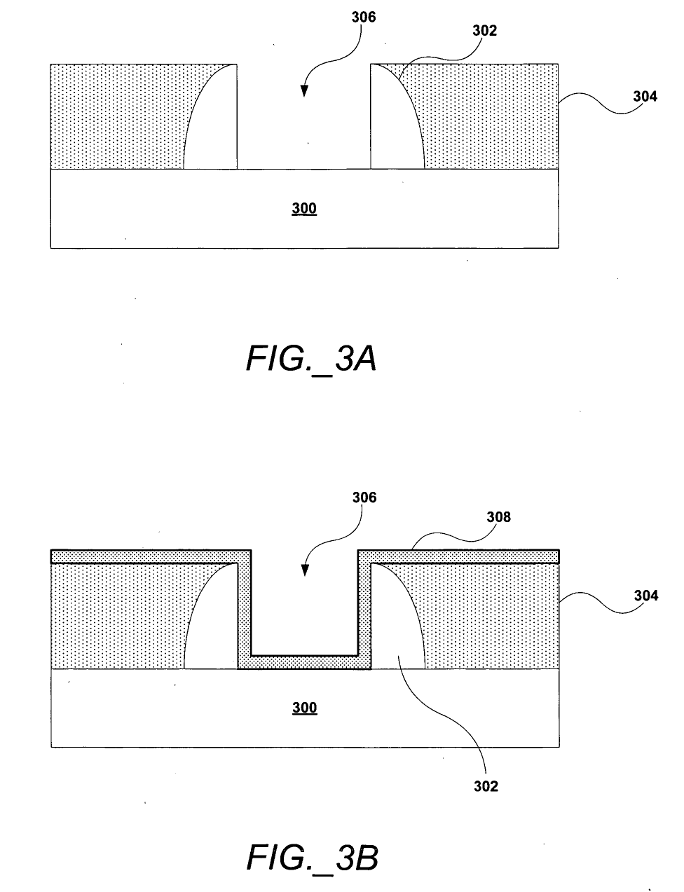

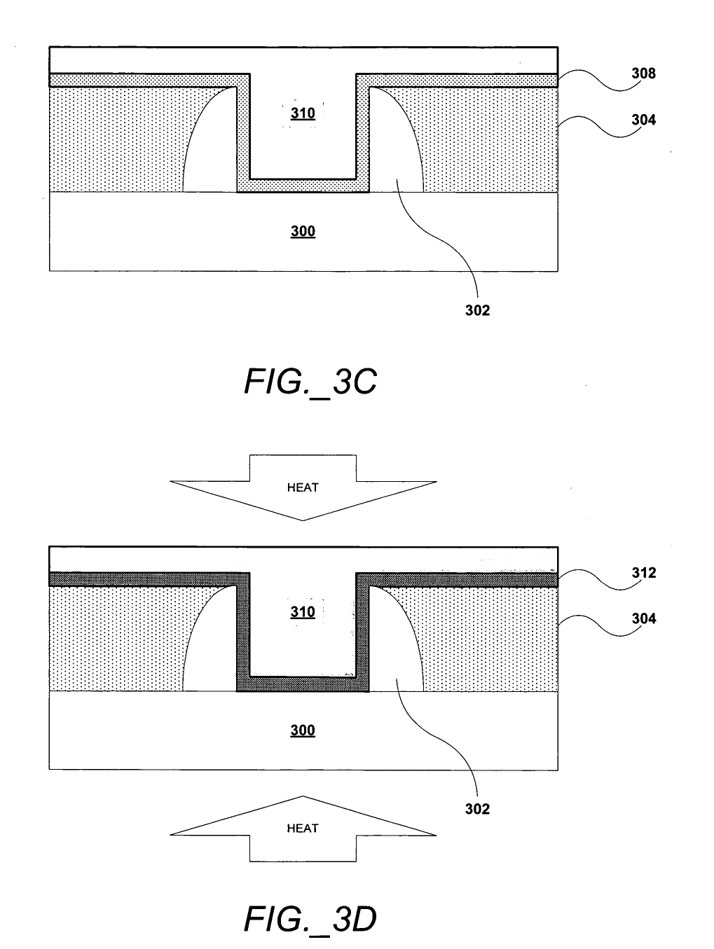

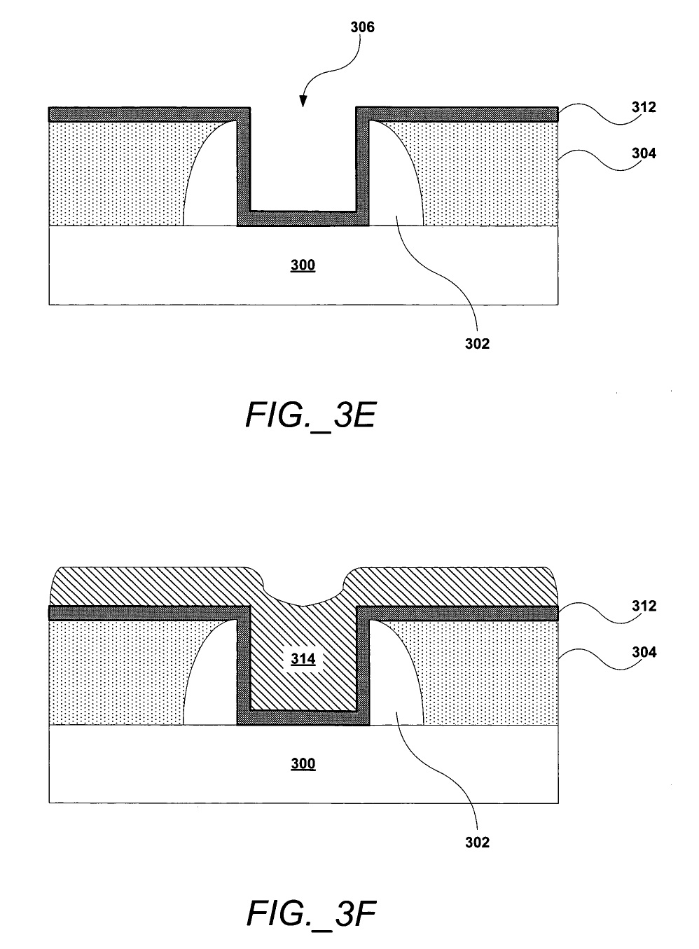

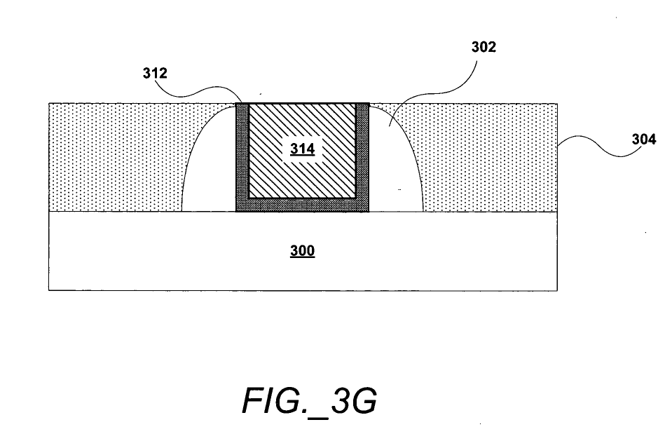

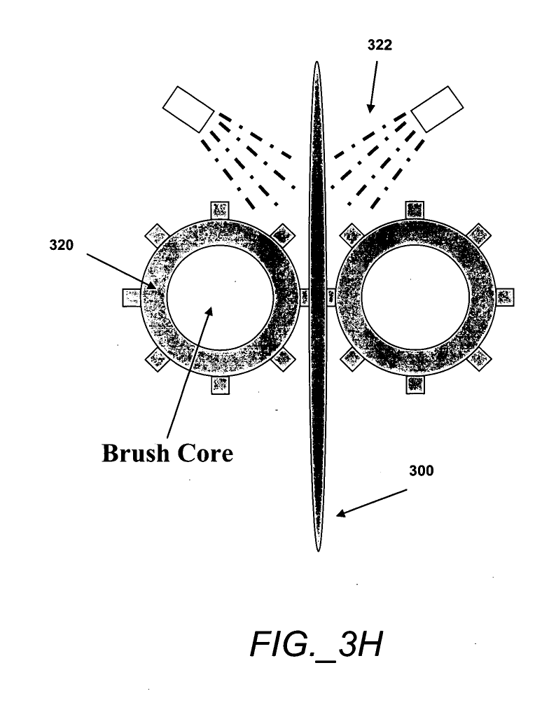

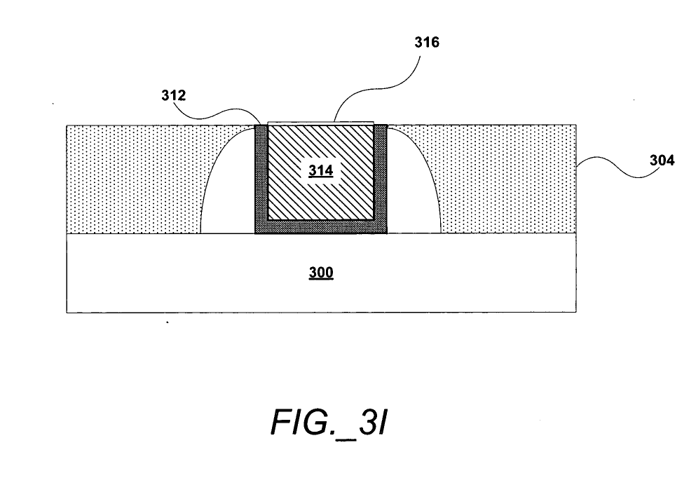

FIG. 2 is an in-situ process 200, in accordance with an implementation of the invention, for forming a transistor gate stack that includes a silanol-based protective layer atop the metal gate electrode. FIGS. 3A through 3I illustrate structures that are formed while carrying out the process 200 of FIG. 2. In the discussion of process 200 below, FIGS. 3A through 3I will be referenced to illustrate the various stages of the process.

First, a substrate is provided upon which the transistor gate stack of the invention may be formed (process 202 of FIG. 2). The substrate may be formed using a bulk silicon or a silicon-on-insulator (SOI) substructure. In other implementations, the substrate may be formed using alternate materials, which may or may not be combined with silicon, that include but are not limited to germanium, indium antimonide, lead telluride, indium arsenide, indium phosphide, gallium arsenide, or gallium antimonide.

FIG. 3A illustrates a provided substrate 300 upon which the transistor gate stack of the invention may be formed. As described above, the substrate 300 is generally formed using a bulk silicon or a silicon-on-insulator substructure, among other materials. Since the substrate 300 is being used to form a MOS transistor, the substrate 300 may also include spacers 302 and an interlayer dielectric (ILD layer) 304, as are well known in the art. The spacers 302 may be separated by a trench region 306, and it is within this trench region 306 that the transistor gate stack will be formed. The spacers 302 may be formed using conventional materials, including but not limited to silicon nitride. The ILD layer 304 may be formed using known materials, including but not limited to carbon doped oxide (CDO) and silicon dioxide (SiO₂). Although not shown, the substrate 300 may also include isolation structures, such as shallow trench isolation structures (STI), that are used to separate the active regions of adjacent transistors.

A high-k gate dielectric layer may be formed within the trench between the spacers (204 of FIG. 2). In some implementations, the high-k gate dielectric layer may be formed on the substrate using a conventional deposition process, including but not limited to chemical vapor deposition (CVD), low pressure CVD, plasma enhanced chemical vapor deposition (PECVD), physical vapor deposition (PVD), atomic layer deposition (ALD), spin-on dielectric processes (SOD), or epitaxial growth. The high-k gate dielectric layer may be formed using materials that include, but are not limited to, hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. Although a few examples of materials that may be used to form high-k gate dielectric layer are described here, that layer may be formed using other materials that serve to reduce gate leakage.

FIG. 3B illustrates the deposition of a high-k gate dielectric layer 308 atop the substrate 300. As shown, the high-k gate dielectric layer 308 conformally blankets the entire substrate 300, including the spacers 302 and the ILD layer 304. The trench region 306 remains as the deposition is highly conformal. Alternately, the high-k date dielectric layer 308 may be formed using a material that is not conformal.

After the high-k gate dielectric layer is formed, a capping layer may be deposited on the high-k gate dielectric layer (206 of FIG. 2). The capping layer may protect the high-k dielectric layer during a subsequent annealing process. In implementations of the invention, the capping layer may comprise polysilicon and may be deposited on the high-k gate dielectric layer using a conventional deposition process. Deposition processes that may be used for the capping layer include, but are not limited to, CVD, PECVD, PVD, and ALD.

FIG. 3C illustrates the deposition of a polysilicon capping layer 310 atop the high-k gate dielectric layer 308. As shown, the capping layer 310 blankets the entire surface of the high-k gate dielectric layer 308. In FIG. 3C, the deposition of the capping layer 310 is not conformal, therefore the trench region 306 is filled with polysilicon.

An annealing process may then be carried out on the high-k gate dielectric layer (208 of FIG. 2). In some implementations, the annealing process may take place at a temperature at or exceeding around 600° C. Such an anneal may modify the molecular structure of high-k gate dielectric layer to create an annealed gate dielectric layer that may demonstrate improved process control and reliability, resulting in improved device performance. During the annealing process, the capping layer serves to inhibit the growth of oxide on the high-k dielectric layer.

FIG. 3D illustrates the application of an annealing process to the high-k gate dielectric layer 308. Heat is applied to the entire structure which includes the substrate 300, the spacers 302, the ILD layer 304, the high-k gate dielectric layer 308, and the capping layer 310. The annealing process modifies the molecular structure of high-k dielectric material, resulting in an annealed high-k gate dielectric layer 312 that demonstrates improved process control and reliability, resulting in improved device performance.

After the annealing process, the capping layer is removed to re-expose the annealed high-k gate dielectric layer, as well as the trench region that is between spacers (210 of FIG. 2). In implementations of the invention, a wet etch process or a dry etch process targeted for the material used in the capping layer, such as polysilicon, is applied to remove the capping layer. During the etching process, the annealed high-k gate dielectric layer may function as an etch stop layer without compromising reliability and performance. The etching process will therefore remove the capping layer while leaving the annealed high-k gate dielectric layer intact.

FIG. 3E illustrates the removal of the capping layer 310 to expose the annealed high-k gate dielectric layer 312, as well as the trench region 306 that is positioned between the spacers 302. As described above, etching and cleaning processes may be used to remove the capping layer 310.

A metallization process is then carried out to deposit a metal layer onto the annealed high-k gate dielectric layer (212 of FIG. 2). The metal deposition covers the annealed high-k gate dielectric layer and fills the trench region with metal. Well known metal deposition processes, such as CVD, PVD, ALD, sputtering, electroplating, or electroless plating, may be used to deposit the metal layer. The metal that is deposited will form the metal gate electrode, therefore, metals that may be used in the metallization process include metals or metal alloys that are conventionally used for metal gate electrodes. For instance, in some implementations, substantially pure aluminum metal is used. In other implementations, the metal used may be one or a combination of the following metals: aluminum, copper, ruthenium, palladium, platinum, cobalt, nickel, ruthenium oxide, tungsten, titanium, tantalum, titanium nitride, tantalum nitride, hafnium, zirconium, a metal carbide, germanium, tin, or a conductive metal oxide, as well as alloys that include any of the above listed materials.

FIG. 3F illustrates the deposition of an aluminum metal layer 314 atop the annealed high-k gate dielectric layer 312 that fills the trench region 306. As shown, the aluminum metal layer 314 not only fills the trench region 306 but also deposits over portions of the ILD layer 304 as well.

A chemical mechanical polishing (CMP) process is then used to planarize and remove excess aluminum metal (214 of FIG. 2). The CMP process may also remove excess portions of the annealed high-k gate dielectric layer. CMP is well known in the art and generally involves the use of a rotating polishing pad and an abrasive, corrosive slurry on a semiconductor wafer. The polishing pad and the slurry physically grind flat the microscopic topographic features until the metal layer is planarized. In accordance with implementations of the invention, the CMP process continues in order to remove unnecessary portions of the metal layer and the high-k dielectric layer.

FIG. 3G illustrates the aluminum metal layer 314 and the annealed high-k gate dielectric layer 312 after a CMP process has been carried out. The CMP process planarizes the aluminum metal layer 314 and removes excess portions of metal and high-k dielectric material.

In accordance with implementations of the invention, a post-CMP clean may be performed to remove particles and clean the surface of the planarized aluminum metal while a silanol-based protective layer is formed on a top surface of the planarized aluminum metal (216 of FIG. 2). The silanol-based protective layer substantially reduces or prevents corrosion that may occur during the post-CMP clean when a clean chemistry is used that employs high pH levels. In implementations of the invention, the constituents needed to form the silanol-based protective layer are found in the post-CMP clean chemistry.

FIG. 3H illustrates a post-CMP cleaning process. The post-CMP clean generally occurs within the same tool as the CMP process. For instance, after the substrate 300, such as a semiconductor wafer, is planarized by the CMP process, the substrate 300 is moved to a station where a pair of brushes, such as a pair of roller brushes 320, may scrub both sides of the substrate 300. The brushes 320 are located within the CMP tool. A silanol-modified clean chemistry 322 is dispensed onto the substrate 300 and the brushes 320 to assist in the clean. As will be explained below, the silanol-modified clean chemistry 322 causes a silanol-based protective layer to form on the planarized metal.

FIG. 3I illustrates a silanol-based protective layer 316 that has formed on the metal layer 314. The silanol-based protective layer 316 is selective to the metal in the metal layer 314, therefore, the silanol-based protective layer 316 is confined to the surface of the metal layer 314 and does not form over the high-k dielectric layer 302 or the ILD layer 304. The silanol-based protective layer 316 is relatively thin, with its thickness measured in monolayers.

In accordance with implementations of the invention, a silanol-modified clean chemistry may be formed by adding a silanol-based chemical to a conventional post-CMP clean chemistry. A conventional post-CMP clean chemistry generally consists of an alkaline, water-based solution that includes a cleaning agent such as ammonia. The concentration of ammonia may be 0.1% to 5% in water. Cleaning agents such as ammonium hydroxide, potassium hydroxide, tetramethyl-ammonium hydroxide (TMAH), or a combination of two of more of these cleaning agents, may be added to water to form a conventional post-CMP clean chemistry. The concentration of these cleaning agents may range from 0.1% to 10% in water. The conventional post-CMP clean chemistry may have a pH level that is within the range of pH 8 to pH 12.

A silanol-based chemical may be formed within this conventional post-CMP clean chemistry to generate the silanol-modified clean chemistry of the invention. In some implementations, the silanol-based chemical may be directly added to the post-CMP clean chemistry. In other implementations, certain chemicals may be added to the post-CMP clean chemistry that will hydrolyze to form the silanol-based chemical, such as silane coupling agents or tetraethylorthosilicate (TEOS).

In some implementations, the silanol-based chemical is formed by adding a silane coupling agent to the post-CMP clean chemistry. Conventional silane coupling agents are organosilane compounds having at least two different types of molecular groups bonded to a silicon atom in a molecule. The first group on the silane coupling agent (referred to herein as R′) may be reactive and capable of bonding to various inorganic materials such as glass, metals, silica sand and the like. Examples of such groups include, but are not limited to, methoxy groups (—OCH₃), ethoxy groups (—OCH₂CH₃), and silanolic hydroxy groups (—SiOH or silanol). The key group is the silanolic hydroxy or silanol group. In aqueous solution, both the methoxy and ethoxy groups are hydrolyzed to form these reactive silanolic hydroxyl or silanol groups. The second group on the silane coupling agent (referred to herein as R″) may include any number of reactive or non-reactive ligand attachments that may have hydrophobic or hydrophilic character. Such ligand attachments include, but are not limited to, hydrocarbons, amines, carboxylic acid, sulphates, phosphates, and polyethers, cationic polar groups, and anionic polar groups.

When added to the post-CMP clean chemistry, the silane coupling agent may react to form the silanol-based chemical. Examples of silane coupling agents that may be used to form silanol-based chemicals in implementations of the invention include, but are not limited to, chemistries that take the form:
R″_{y}—Si(OR′)_{z}
where y=4−z, where R′=CₙH₂ₙ₊₁, where R″=CₙH₂ₙ₊₁ or CₙH₂ₙCOOH, and where n=1 to 18. The hydrocarbon groups may be linear or branched. Furthermore, in solution, the R′ groups may hydrolyze to form reactive SiOH groups. As will be appreciated by one of skill in the art, the particular silanol-based chemical that is formed will depend on the particular silane coupling agent that is used. For instance, if the silane coupling agent includes the ligand attachment R″, the silanol-based chemical that is formed will also include the ligand attachment R″. The concentration of the silane coupling agent may range from 0.1% to 5% by weight in the post-CMP clean chemistry.

In other implementations, Si(OCH₂CH₃)₄, known as tetraethylorthosilicate or TEOS, may be used because TEOS reacts in the aqueous clean chemistry to take on hydroxyl groups and become a silanol-based chemical. If TEOS is used, a TEOS concentration of around 0.1% to 5% by weight may be added for aqueous based solutions. In some implementations, a TEOS concentration of 0.5% to 3% by weight may be used for aqueous based solutions.

As will be recognized by those of skill in the art, the hydrolysis of the silane coupling agents or the TEOS in the aqueous clean chemistry solution produces volatile organic compounds such as ethanol in addition to the silanol-based chemical. Accordingly, in implementations of the invention, the volatile organic compounds may be removed from the silanol-modified clean chemistry prior to using the clean chemistry on a substrate. This is particularly necessary in semiconductor fabrication units where the volatile organic compounds may cause the volatile organic content limits of the fabrication unit to be exceeded.

When the silanol-modified clean chemistry is applied to the metal layer, the high pH level causes hydroxyl groups to attach to the surface of the metal, thereby forming metal hydroxyl groups across the surface of the metal layer. These metal hydroxyl groups may then react with the silanol-based chemical that is included in the silanol-modified clean chemistry. This reaction is a hydrolysis reaction that causes the silanol-based chemical to become covalently bonded to the surface of the metal layer, thereby forming a silanol-based protective layer that covers the metal layer. The silanol-based protective layer substantially limits or prevents the high pH clean chemistry from coming into direct contact with the metal layer. By limiting the interaction between the high pH clean chemistry and the metal layer, corrosion and pitting of the surface of the metal layer is substantially reduced.

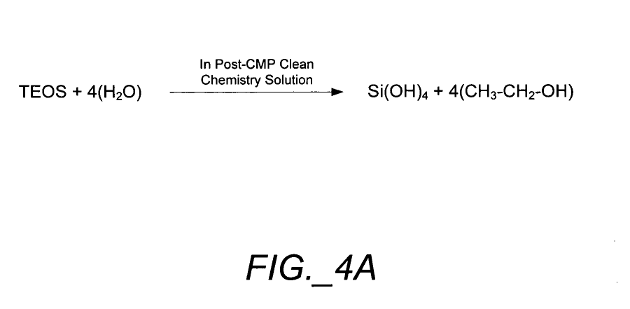

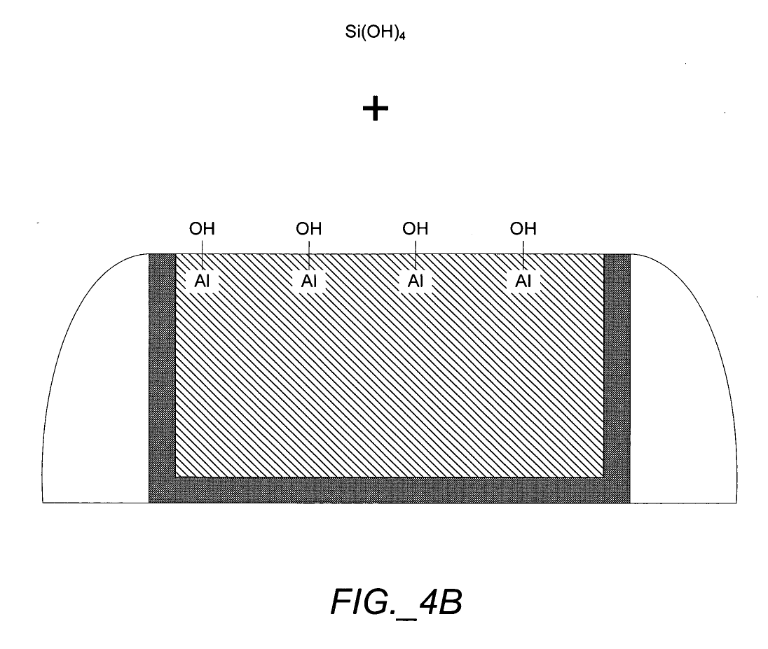

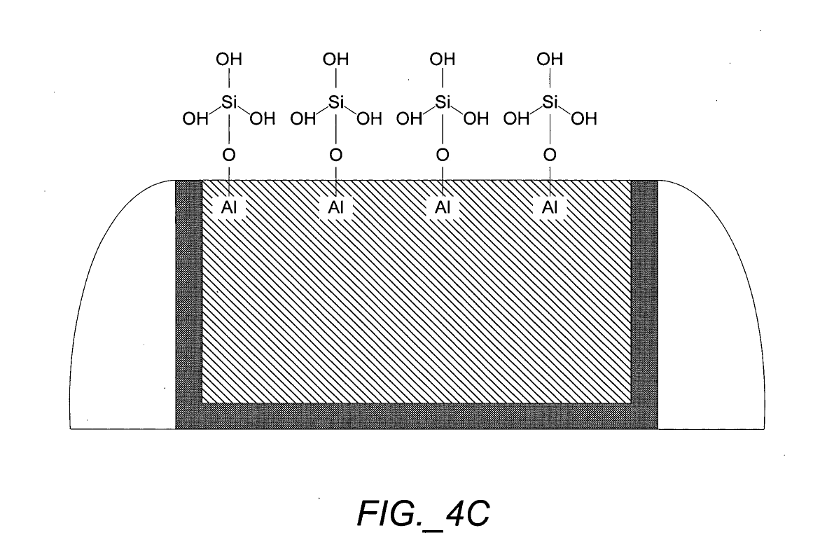

FIGS. 4A to 4C illustrates the formation of a silanol-based protective layer on the metal layer in accordance with implementations of the invention. FIG. 4A demonstrates a reaction that may occur when TEOS is added to a conventional post-CMP clean chemistry to form a silanol-modified clean chemistry. The TEOS reacts with water to form silicic acid (Si(OH)₄) and ethanol. The silicic acid is a silanol-based chemical. Since the TEOS concentration used ranges from 0.1% to 5% by weight, the silicic acid is approximately 0.1% to 5% by weight in the silanol-modified clean chemistry.

FIGS. 4B and 4C demonstrate reactions that may occur when the silanol-modified clean chemistry is applied to the surface of the metal layer. As shown in FIG. 4B, the high pH level of the silanol-modified clean chemistry causes the aluminum metal to take on hydroxyl groups from solution, thereby forming a layer of metal hydroxide (e.g., aluminum hydroxide) across its surface. FIG. 4B therefore illustrates the two chemical species that may undergo a hydrolysis reaction to form a protective layer over the metal layer, i.e., aluminum hydroxide and silicic acid.

FIG. 4C illustrates the result of the hydrolysis reaction. The silanol-based chemical, silicic acid, covalently bonds to the aluminum hydroxide to form a silanol-based protective layer. In some implementations this protective layer may be continuous, while in other implementations this protective layer may be discontinuous. As shown, the silanol-based protective layer is only a few monolayers thick. In some implementations, a polymerization reaction may be induced to cause at least a portion of the silanol molecules to bond to one another. As shown, the metal surface is now stabilized or covered by a thin silanol-based protective layer that suppresses surface oxidation and limits or discourages the high pH clean chemistry from coming into contact with the aluminum metal. Accordingly, corrosion of the surface of the aluminum metal caused by the high pH clean chemistry may be substantially reduced.

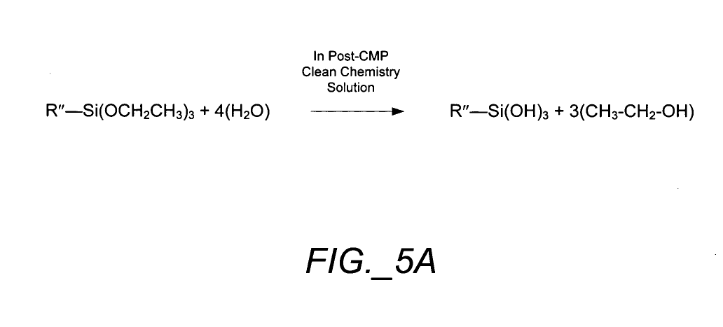

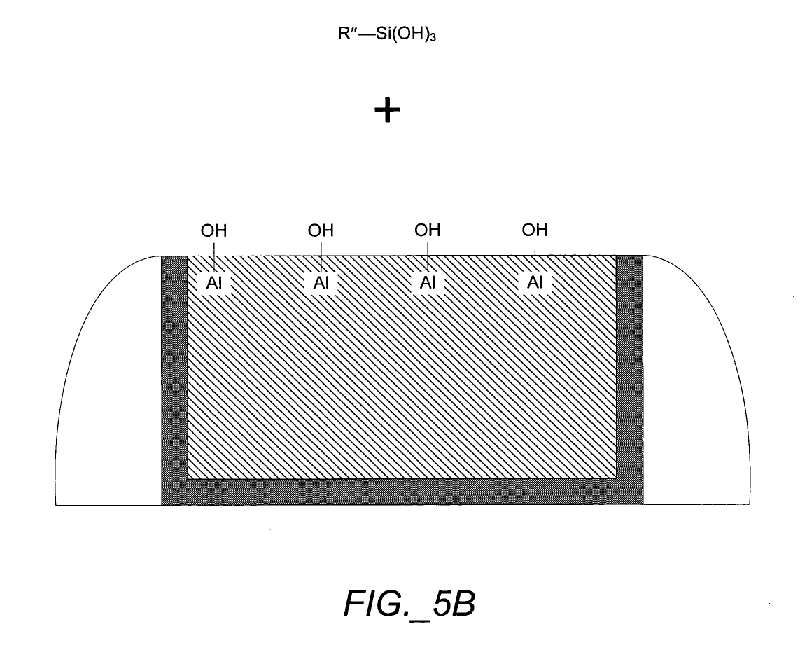

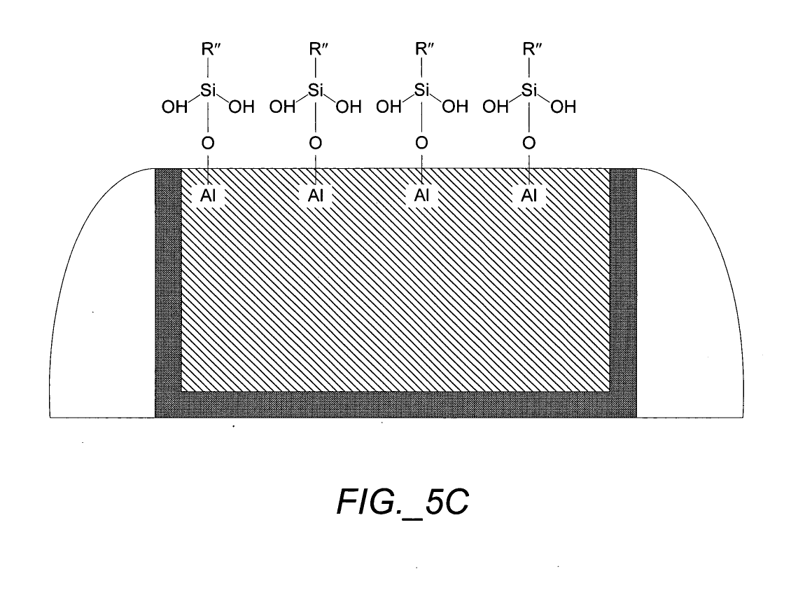

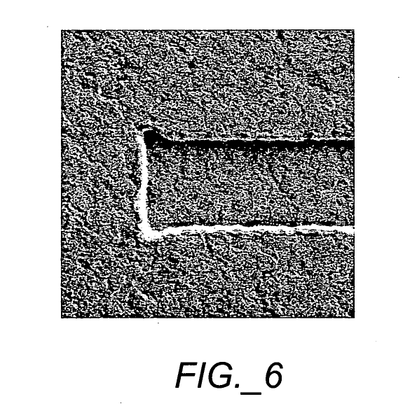

FIGS. 5A to 5C illustrate the formation of a silanol-based protective layer on the metal layer in accordance with another implementation of the invention. FIG. 5A demonstrates a reaction that may occur when a particular silane coupling agent, shown as R″—Si(OCH₂CH₃)₃, is added to a conventional post-CMP clean chemistry to form a silanol-modified clean chemistry. In this implementation, the silane coupling agent includes the ligand attachment R″. As will be explained below, the degree of protection afforded by the silanol-based protective layer may be modified or tuned by choosing the appropriate ligand attachment. As shown in FIG. 5A, the silane coupling agent reacts with water to form a silanol-based chemical and ethanol. The ligand attachment R″ remains bonded to the silanol-based chemical.

FIGS. 5B and 5C demonstrate reactions that may occur when the silanol-modified clean chemistry is applied to the surface of the metal layer. As shown in FIG. 5B, the high pH level of the clean chemistry causes the aluminum metal to take on hydroxyl groups from solution, thereby forming a layer of aluminum hydroxide. FIG. 5B therefore illustrates the two chemical species that may undergo a hydrolysis reaction to form a protective layer over the metal layer, i.e., aluminum hydroxide and the ligand containing silanol-based chemical.

FIG. 5C illustrates the result of the hydrolysis reaction. The silanol-based chemical covalently bonds to the aluminum hydroxide to form a silanol-based protective layer. The ligand attachments R″ form an outer portion of the silanol-based protective layer. As before, this silanol-based protective layer may be continuous or discontinuous. The metal surface is now stabilized or covered by a silanol-based protective layer that suppresses surface oxidation and limits or discourages the clean chemistry from coming into contact with the aluminum metal. Accordingly, corrosion of the surface of the aluminum metal caused by the high pH clean chemistry may be substantially reduced.

The ligand attachment that is used in the silanol-modified clean chemistry of the invention is chosen based on its effect on the silanol-based protective layer. If the ligand consists of a hydrophobic group, for example, the ligand attachment will tend to repel water from the surface of the metal layer when the silanol-based protective layer is formed. This will increase the degree of protection that is provided by the silanol-based protective layer and decrease the amount of cleaning that occurs. If, on the other hand, the ligand attachment consists of a hydrophilic group, the ligand attachment will tend to draw water to the surface of the metal layer, thereby decreasing the degree of protection that is provided and increasing the amount of cleaning that occurs. A user may therefore tailor the degree of hydrophilicity or hydrophobicity of the silanol-based protective layer by choosing an appropriate ligand attachment or mixture of ligands.

Examples of hydrophobic ligands include, but are not limited to, hydrocarbons, both linear and branched (e.g., CₙH₂ₙ₊₁). Hydrocarbons are large as C₁₈ may be used, although in most implementations, hydrocarbons around C₁₀ are preferred. The size of the ligand influences its hydrophobic properties. Larger molecular weights or branched hydrocarbons tend to induce greater steric effects, such as steric hindrance or steric resistance, that physically prevent the clean chemistry from reaching the surface of the metal layer.

Examples of hydrophilic ligands include, but are not limited to, amines, carboxylic acid, sulphates, phosphates, and polyethers, as well as other cationic and anionic polar groups. As noted above, these ligands may be used to increase the amount of cleaning that occurs. In some implementations, a combination of hydrophilic and hydrophobic ligands may be used in the protective layer of the invention to optimize corrosion reduction and cleaning.

The effect that the protective layer of the invention has on the aluminum metal is demonstrated in the SEM image of FIG. 6, where aluminum metal is shown that has been cleaned using a modified post-CMP clean chemistry in accordance with an implementation of the invention. As shown in FIG. 6, the surface of the aluminum metal is very similar to the surface of the uncleaned aluminum metal shown in FIG. 1A. Furthermore, one of skill in the art will readily recognize the substantial reduction in corrosion and pitting between aluminum metal that is cleaned using a conventional post-CMP clean chemistry (i.e., FIG. 1B) and aluminum metal that is cleaned using a modified post-CMP clean chemistry in accordance with implementations of the invention (i.e., FIG. 6).

As such, implementations of the invention enable aluminum metal used in integrated circuits, such as metal gate electrodes, to be cleaned with chemicals having high pH levels. The aluminum surface can be protected in-situ without adding additional process steps. Furthermore, dilute concentrations of the TEOS may be used, thereby making the process cost-effective. And because the reaction rate of the chemistry with the metal surface is rapid, the overall metal trench loss is minimized.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

1. A method comprising:
providing a substrate that includes a high-k gate dielectric layer and a metal layer that has been deposited on the high-k gate dielectric layer;
planarizing the metal layer using a chemical mechanical polishing process;
dispensing a silanol-modified clean chemistry onto the planarized metal layer; and
scrubbing the planarized metal layer with the silanol-modified clean chemistry.

2. The method of claim 1, wherein the dispensing of the silanol-modified clean chemistry causes a silanol-based protective layer to form on a surface of the planarized metal layer.

3. The method of claim 1, wherein the metal layer comprises at least one of aluminum, copper, ruthenium, palladium, platinum, cobalt, nickel, ruthenium oxide, tungsten, titanium, tantalum, titanium nitride, tantalum nitride, hafnium, zirconium, a metal carbide, or a conductive metal oxide.

4. The method of claim 1, wherein the silanol-modified clean chemistry comprises a post-CMP clean chemistry that includes a silanol-based chemical.

5. The method of claim 4, wherein the silanol-based chemical is included by adding TEOS to the post-CMP clean chemistry.

6. The method of claim 5, wherein a TEOS concentration in the post-CMP clean chemistry is greater than or equal to 0.1% by weight and less than or equal to 5% by weight.

7. The method of claim 5, wherein a TEOS concentration in the post-CMP clean chemistry is greater than or equal to 0.5% by weight and less than or equal to 3% by weight.

8. The method of claim 4, wherein the silanol-based chemical is included by adding a silane coupling agent to the post-CMP clean chemistry.

9. The method of claim 8, wherein the silane coupling agent concentration in the post-CMP clean chemistry is greater than or equal to 0.1% by weight and less than or equal to 5% by weight.

10. The method of claim 4, wherein the silanol-based chemical includes a hydrophobic ligand attachment.

11. The method of claim 4, wherein the silanol-based chemical includes a hydrophilic ligand attachment.

12. The method of claim 4, wherein the silanol-based chemical includes a mixture of hydrophobic and hydrophilic ligand attachments.

13. A method comprising:
providing a post-CMP clean chemistry; and
forming a silanol-based chemical within the post-CMP clean chemistry.

14. The method of claim 13, wherein the forming of the silanol-based chemical comprises adding TEOS to the post-CMP clean chemistry, wherein the TEOS reacts with water in the post-CMP clean chemistry to form a silanol-based chemical.

15. The method of claim 14, wherein a sufficient quantity of TEOS is added to create a TEOS concentration in the post-CMP clean chemistry that is greater than or equal to 0.1% by weight and less than or equal to 5% by weight.

16. The method of claim 14, wherein a sufficient quantity of TEOS is added to create a TEOS concentration in the post-CMP clean chemistry that is greater than or equal to 0.5% by weight and less than or equal to 3% by weight.

17. The method of claim 13, wherein the forming of the silanol-based chemical comprises adding a silane coupling agent to the post-CMP clean chemistry, wherein the silane coupling agent reacts with water in the post-CMP clean chemistry to form a silanol-based chemical.

18. The method of claim 17, wherein a sufficient quantity of the silane coupling agent is added to create a silane coupling agent concentration in the post-CMP clean chemistry that is greater than or equal to 0.1% by weight and less than or equal to 5% by weight.

19. The method of claim 17, wherein the silanol-based chemical includes a ligand attachment.

20. The method of claim 19, wherein the ligand is included in the silane coupling agent and wherein the ligand is selected from the group consisting of hydrocarbons, amines, carboxylic acid, sulphates, phosphates, and polyethers, cationic polar groups, and anionic polar groups.

21. A post-CMP clean chemistry comprising:
water;
an alkaline cleaning agent, wherein the alkaline cleaning agent concentration ranges from 0.1% to 10% in the water; and
a silanol-based chemical, wherein the silanol-based chemical concentration ranges from 0.1% to 5% by weight in the water.

22. The post-CMP clean chemistry of claim 21, wherein the alkaline cleaning agent is selected from the group consisting of ammonia, ammonium hydroxide, potassium hydroxide, and TMAH.

23. The post-CMP clean chemistry of claim 21, wherein the silanol-based chemical is formed from TEOS.

24. The post-CMP clean chemistry of claim 21, wherein the silanol-based chemical is formed from a silane coupling agent.

25. The post-CMP clean chemistry of claim 24, wherein the silanol-based chemical comprises CₙH₂ₙCOOH—Si(OH)₃, and wherein Cₙ comprises a linear or branched hydrocarbon ranging from C₁ to C₁₈.

26. The post-CMP clean chemistry of claim 24, wherein the silanol-based chemical comprises CₙH₂ₙ₊₁—Si(OH)₃, and wherein Cₙ comprises a linear or branched hydrocarbon ranging from C₁ to C₁₈.

27. The post-CMP clean chemistry of claim 24, wherein the silanol-based chemical includes a ligand, and wherein the ligand is included in the silane coupling agent.

28. The post-CMP clean chemistry of claim 21, wherein the pH level of the clean chemistry is greater than or equal to pH 8 and less than or equal to pH 12.

29. A transistor gate stack comprising:
an annealed high-k gate dielectric layer formed within a trench between a first spacer and a second spacer, wherein the annealed high-k gate dielectric layer is formed on the sidewalls and bottom of the trench;
a metal layer on the annealed high-k gate dielectric layer; and
a silanol-based protective layer on a top surface of the metal layer.

30. The transistor gate stack of claim 29, wherein the annealed high-k gate dielectric layer comprises at least one of hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

31. The transistor gate stack of claim 29, wherein the metal layer comprises at least one of aluminum, copper, ruthenium, palladium, platinum, cobalt, nickel, ruthenium oxide, tungsten, titanium, tantalum, titanium nitride, tantalum nitride, hafnium, zirconium, a metal carbide, or a conductive metal oxide.

32. The transistor gate stack of claim 29, wherein the silanol-based protective layer comprises a silanol-based chemical that is bonded to the top surface of the metal layer.

33. The transistor gate stack of claim 32, wherein the silanol-based chemical includes a ligand attachment.

34. The transistor gate stack of claim 33, wherein the ligand attachment is hydrophobic.

35. The transistor gate stack of claim 33, wherein the ligand attachment is hydrophilic.

36. The transistor gate stack of claim 33, wherein the ligand attachment is selected from the group consisting of hydrocarbons, amines, carboxylic acid, sulphates, phosphates, and polyethers, cationic polar groups, and anionic polar groups.
